(19) United States
(12) Patent Application Publication
(10) Pub. No.: US 2004/0067654 A1
(43) Pub. Date: Apr. 8, 2004

(54) Method of reducing wafer etching defect

(75) Inventors: Chun-Wei Chen, Hsinchu City (TW); Hong-Long Chang, Hsinchu City (TW); Nien-Yu Tsai, Taipei City (TW)

Correspondence Address: Ladas & Parry, 26 West 61st Street, New York, NY, 10023, US

(73) Assignee: PROMOS TECHNOLOGIES, INC.

(21) Appl. No.: 10/265,826

(22) Filed: Oct. 7, 2002

(51) Int. Cl. H01L 21/302; H01L 21/461

(52) U.S. Cl. 438/706; 438/712; 438/717

(57) ABSTRACT

The present invention relates to a method of reducing needle-like defects generated on a wafer rim in an etching process, wherein the etching process using both a photoresist material and hardmask material as a mask. After removing the photoresist material and the hardmask material, said method comprising the steps of: (i) depositing the photoresist material on the wafer again; (ii) performing wafer edge exposure (WEE) to form a ring of the wafer edge; and (iii) performing dry etching to the exposed ring of wafer edge to remove the needle-like defects generated on the wafer edge.

### FIELD OF INVENTION

The present invention relates to a method of reducing needle-like defects on the wafer rim generated after the etching process, especially relates to a method of performing dry etching process to remove needle-like defects generated on the wafer rim.

### BACKGROUND OF THE INVENTION AND RELATED ART

Most of electronic products are developed to have smaller dimension and lighter weight in order to meet the requirement by the market. The line width of an electronic component is reduced from 0.2 μm to 0.14 μm in order to meet this tendency and will be even smaller in the future. Traditional photoresist materials are no longer applicable to such a smaller line width. For example, the thickness of a mask during the etching process is not sufficient to resist the etchant. In other words, the etching selectivity of the photoresist is lower. Thus, an alternative way is to add a layer of higher etching sensitive material (which has a higher etching selectivity), the hardmask material, so as to achieve a sufficient thickness of the mask to resist the etchant. However, there is a side effect of using the hardmask material. That is, needle-like defects might be generated on the wafer rim. The reason is illustrated in accordance with the drawings as follows:

FIGS. 1 to 3 are cross-sectional views of a wafer of a prior art manufacturing process of 0.2 μm or smaller line width. First, a layer of pad oxide thin film 4 is deposited onto a silicon substrate 2 before performing a lithographic process. Next, a layer of hardmask material 6 is deposited onto said thin oxide film 4, for example, nitride, polysilicon and BSG. Next, a layer of photoresist material (not shown in the drawings) is deposited onto said hardmask material 6. Next, a lithographic process is performed so as to expose and develop patterns. Next, an etching process, for example, for forming deep trenches, is performed the patterns onto said hardmask material 6 and said thin oxide film 4. Said photoresist (not shown in the drawings) is removed after the etching process is completed. Next, the etching process is performed so as to transfer the patterns of said hardmask material 6 and said thin oxide film 4 onto the silicon substrate 2 as shown in FIG. 2. Next, said hardmask material 6 is removed after the transfer of the patterns is completed as shown in FIG. 3. It is emphasized that the above mentioned lithographic and etching processes are only illustrated briefly. The complete manufacturing processes are well known to persons skilled in the art and are not illustrated in detail.

Needle-like defects are usually generated on the wafer rim after the above-mentioned manufacturing processes are completed, as shown in FIG. 4. The reasons for forming such defects are listed as follows. First, the hardmask material covered on the wafer rim can not be as uniform and complete as the hardmask material covered on the center of the wafer. Thus, the hardmask material can not offer sufficient protection of the wafer rim against etching. Second, the defects are caused by the roughness of the wafer itself. In general, the wafer rim is rougher than the center of the wafer. Thus, the thickness of the hardmask material deposited on the wafer rim is uneven, which causes the etching degree to be uneven and forms needle-like defects. Needle-like defects generated on the wafer rim are usually broken off during subsequently manufacturing processes, and thus cause contamination of other parts of the wafer and decrease the yield of the components manufactured with the wafer. Thus, it becomes an important issue to increase the yield and the benefit by removing needle-like defects on the wafer rim generated in the above-mentioned wafer processes.

### SUMMARY OF THE INVENTION

The object of the present invention is to provide a method of removing needle-like defects generated on a wafer rim during the wafer manufacturing process of 0.2 mm or smaller line width using conventional techniques. The method of the present invention can reduce needle-like defects generated on a wafer edge so as to increase the yield of semiconductor devices manufactured on the wafer.

### BRIEF DESCRIPTION OF THE DRAWINGS

This invention will be better understood with reference to the accompanying drawings in which:

FIGS. 1 to 3 are cross-sectional views of a wafer in wafer processes of 0.2 μm or smaller line width using conventional techniques;

FIG. 4 is a partially enlarged view of needle-like defects generated on a wafer rim “A” as shown in FIG. 3;

FIGS. 5 and 6 are cross-sectional views of needle-like defects generated on a wafer rim removed according to the method of the present invention;

FIG. 7 is a partially enlarged view of needle-like defects generated on a wafer edge removed according to the method of the present invention as shown in FIG. 6; and

FIG. 8 is a flow chart of the method of removing needle-like defects generated on a wafer rim according to the present invention.

### DETAILED DESCRIPTION OF THE INVENTION

The preferred embodiment of the present invention will be described below with reference to the accompanying drawings. The same element in the drawings is represented with the same reference numeral.

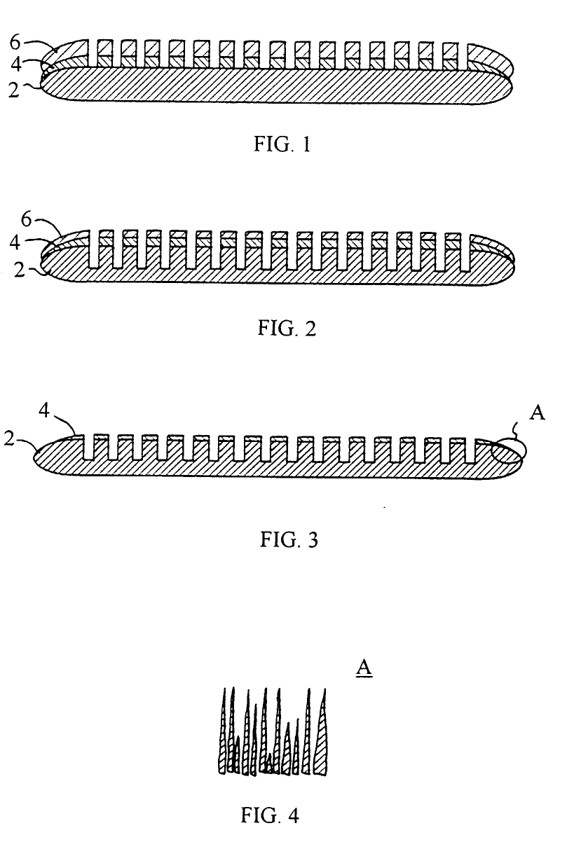

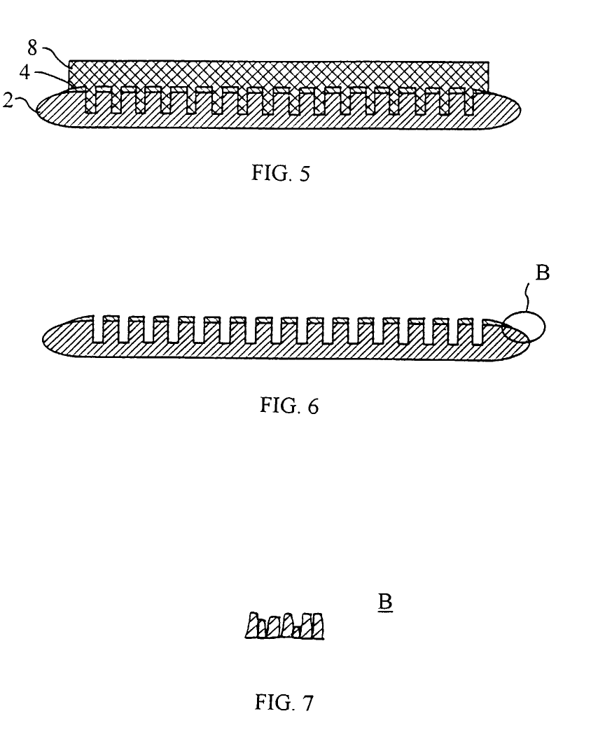

As shown in FIG. 5, a layer of photoresist material 8 with a thickness of about 1 to 3 μm is deposited on a wafer after the wafer processes of conventional techniques as shown in FIGS. 1 to 4 are completed. Next, a wafer edge exposure (WEE) of a non-device area of a wafer rim to form an extreme ring non-device area with a width of about 0 to 3 mm (preferably less than 1 mm). Next, the exposed wafer rim ring area (including silicon substrate 2 and oxide 4, mainly silicon substrate 2) is etched. It is better to use a reactive ion etching (RIE) gas (such as NF₃ and SF₆) to perform isotropic etching.

As shown in FIG. 6, a step of removing the photoresist material 8 can be included after the above-mentioned processes are completed.

As shown in FIG. 7, needle-like defects generated on the wafer rim can be improved after the dry etching is performed. FIG. 7 shows a partially enlarged view of the wafer rim “B” of FIG. 6. By way of reducing needle-like defects on the wafer rim, the yield of the devices manufactured on the wafer is improved.

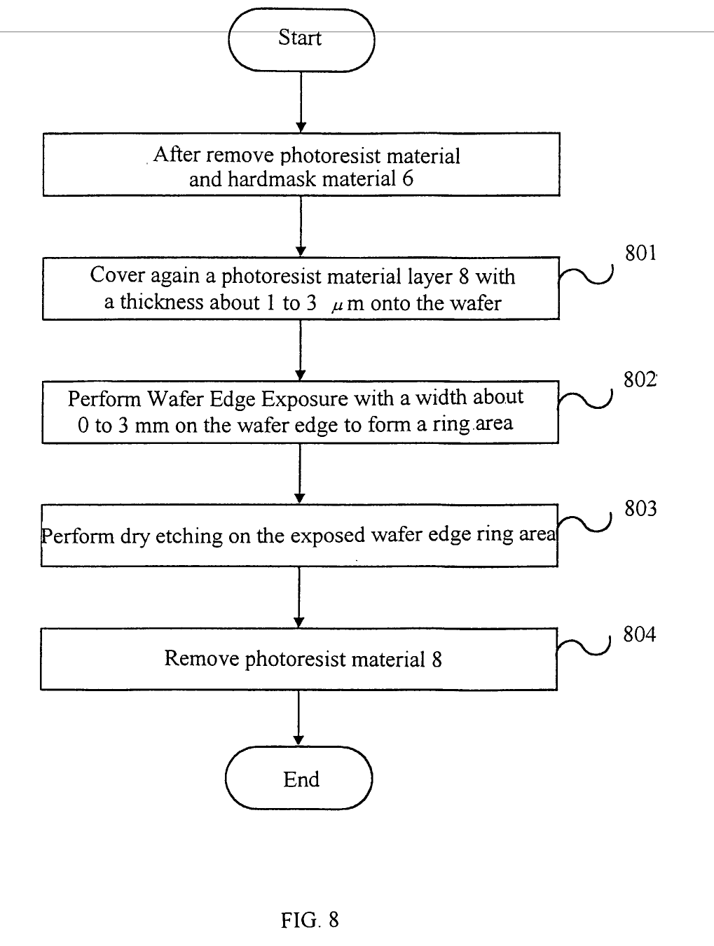

FIG. 8 is a flow chart of the method of removing needle-like defects generated on a wafer rim according to the present invention. In step 801, a layer of photoresist material 8 with a thickness of about 1 to 3 μm is deposited after the conventional techniques of wafer processes shown in FIGS. 1 to 4. Next, in step 802, wafer edge exposure (WEE) of a non-device area of a wafer rim is performed to form a ring area with a width of about 0 to 3 mm (preferably less than 1 mm). Next, in step 803, dry etching of the exposed wafer ring area (including silicon substrate 2 and oxide 4, mainly silicon substrate 2) is performed. It is better to use a reactive ion etching (RIE) gas (such as NF₃, SF₆, etc.) to perform isotropic etching. The step of removing said photoresist material 8 can be included after the above-mentioned steps are performed.

With the above descriptions, it is obvious that the embodiments and description are not intended to limit the invention. The invention may be varied in many ways. Such variations are not to be regarded as a departure from the spirit and scope of the invention, and all such modifications as would be obvious to one skilled in the art and fall within the scope of the following claims.

What is claimed is:

1. A method for reducing needle-like defects generated on a wafer rim after an etching process, wherein said etching process using a photoresist material and a hardmask material as a mask, after removing said photoresist material and said hardmask material, said method comprising the following steps of:
(i) depositing said photoresist material on said wafer again;
(ii) performing wafer edge exposure (WEE) to clean up a ring of photoresist at the wafer rim; and
(iii) dry etching said ring to remove the needle-like defects generated on the wafer rim.

2. The method of claim 1, further comprising the step of:
(iv) removing said photoresist material.

3. The method of claim 1, wherein the thickness of the photoresist material of step (i) is between 1 and 3 μm.

4. The method of claim 1, wherein the width in performing wafer edge exposure of step (ii) is between 0 and 3 mm.

5. The method of claim 4, wherein the width in performing wafer edge exposure of step (ii) is less than 1 mm.

6. The method of claim 1, wherein the dry etching of step (iii) is to perform isotropic etching using a reactive ion etching gas.

7. The method of claim 6, wherein the reactive ion etching gas used in step (iii) is NF₃.

8. The method of claim 6, wherein the reactive ion etching gas used in step (iii) is SF₆.

9. The method of claim 1, wherein said hardmask material is a BSG material.

10. The method of claim 1, wherein said hardmask material is a nitride material.

11. The method of claim 1, wherein said hardmask material is a polysilicon material.

12. The method of claim 1, wherein said etching step is used for forming deep trenches.
